(19) United States
(12) Patent Application Publication
(10) Pub. No.: US 2001/0036225 A1
(43) Pub. Date: Nov. 1, 2001

(54) Coefficient update method and receive method of time domain equalizer of DMT system, DMT system and DMT modem

(75) Inventor: Hiroyasu Murata, Kawasaki (JP)

Correspondence Address: HELFGOTT & KARAS, P.C., EMPIRE STATE BUILDING, 60th Floor, New York, NY, 10118, US

(73) Assignee: FUJITSU LIMITED

(21) Appl. No.: 09/745,044

(22) Filed: Dec. 20, 2000

(30) Foreign Application Priority Data
Apr. 28, 2000 (JP) 2000-131591

(51) Int. Cl. H04B 1/38; H04L 5/16; H03H 7/40; H03H 7/30

(52) U.S. Cl. 375/222; 375/232

(57) ABSTRACT

In a coefficient update method for a time domain equalizer of a DMT system, an optimum coefficient is obtained even during a data period. The processing volume for the coefficient update is also decreased. A coefficient of the TEQ 32 is updated by the output of the time domain equalizer (TEQ 32) of the DMT system. Because of this, the transient of the sync symbol where a cyclic prefix is added during the data period can be removed, so the coefficient of the TEQ can be accurately updated even if sync symbols are used. Therefore, the coefficient of the TEQ is updated even during data communication, so the coefficient of the TEQ 32 can be updated according to the change in the characteristics even for a channel where the characteristics change. Since the output of the FFT (36) on the main path at a subsequent stage of the TEQ (32) is used, the processing volume of the FFT for the coefficient correction processing can be decreased.

### BACKGROUND OF THE INVENTION

1. Field of the Invention

The present invention relates to a DMT (Discrete Multitone Modulation) system using multi-carrier modulation technology, and more particularly to an update method for updating a coefficient of a time domain equalizer of a DMT modem.

2. Description of the Related Art

In such a single carrier digital transmission system as QAM (Quadrature Amplitude Modulation), a transmission band is determined by a symbol rate and a carrier frequency. In such a transmission line as a digital subscriber line (particularly metal cable), the optimum transmission band (transmission frequency) of each line is different. Therefore, in a single carrier frequency system, high-speed transmission with a low error rate on each transmission line is difficult.

To solve this problem, a multi-carrier modulation system which uses a plurality of frequencies of carriers has been proposed. In this multi-carrier system, a transfer rate of a carrier at a frequency which causes a large distortion of the line is dropped or the carrier is not used and another carrier can be used to implement high-speed data transmission. The typical system of this type of multi-carrier system is a DMT (Discrete Multitone Modulation) system, which will be described with reference to FIGS. 11 to 14.

As FIG. 11 shows, in the DMT system, a multi-carrier transmitter 100 and a receiver 1000 are connected via a channel 2000 such as a line. In the transmitter 100, serial input data at M·fs bit/s is grouped into Mbit blocks at symbol rate fs by an encoder 110. In a modulator 120, Mbits of each symbol are modulated by N number of separate carriers.

As FIG. 12 shows, the N number of carriers (sub-channels) 0 to N−1 are arranged at an Δf interval along the frequency band T/N. For this modulator 120, IFFT (Inverse Fast Fourier Transfer) is used, which generates N samples (preferably a multiple of 2) of transmission signals for each one of Mbit blocks.

In FIG. 11, a cycle prefix 150 increases the symbol length of a signal from N to N+L so that the transient of a channel 2000, due to the phase discontinuity between each symbol, is removed by the receiver 1000. As FIG. 13 shows, the cyclic prefix L is added before the original data block N. For example, the latter half data x2N−V to x2N−1 of the data block N is added as a cyclic prefix.

This digital sample is converted to an analog signal by a digital-analog converter (DAC), a low pass filter, and a D.C separation converter 130, and is sent to the channel 2000.

Then in the receiver 1000, the D.C separation converter, low pass filter and analog-digital converter (ADC) 1100 convert the analog receive signal to a digital receive signal. A pre-equalizer 1010 equalizes the receive signal using the time base. Because of this, the pre-equalizer 1010 is called a “time domain equalizer (TEQ)”.

A discard prefix 1050 discards the added cyclic prefix L as shown in FIG. 14, and removes the transient area between the symbols from the input of the FFT 1020. The FFT (Fast Fourier Transfer) 1020 demodulates the digital receive signal to the signal in the frequency domain. The FEQ (Frequency Domain Equalizer) 1030 compensates for the intensity and the delay of each sub-channel. The decoder 1040 decodes the data of each symbol and outputs serial data. For details on such a DMT system, see U.S. Pat. No. 5,479,447 for example.

For such a DMT system, coefficient updates to optimize the equalization parameters of the TEQ 1010 according to the characteristics of the channel, that is training, are required. A conventional training process will be described with reference to FIG. 15 to FIG. 17.

As FIG. 15 shows, a PRBS generator 140 generates a fixed length pseudo-random bit string (PRBS). This PRBS passes through an encoder 110, an IFFT 120, and a DAC/LPF/converter 130, and is sent to the channel 2000. In the receiver 1000, the PRBS is converted to the digital receive signal y (D) by the converter/LPF/ADC 1100.

The PRBS generator 1200 of the receiver 1000 generates a copy of PRBS at the transmission side, and the encoder 1250 encodes this copy and generates PRBS signal X′. An update B block 1300 responds to y (D), X′ and Ww (D), and generates a new updated Bu. Here, Ww (D) is a window parameter of the equalizer 1010, and Bu is a response characteristic parameter of the target channel.

This window parameter will now be described with reference to FIG. 17. As a tap adjustment method of an echo canceller performing an update in the frequency domain, conversion to the time domain, windowing and inverse conversion to the frequency domain are known. As shown in FIG. 16, this window technology is for restricting a long response, which is not windowed, in the time domain to an ideal short response by using a predetermined range of the window.

In FIG. 15, a window B block 1400 converts the response parameter Bu in the frequency domain into the time domain, selects a fixed number of continuous samples in the time domain, sets the remains to zero, and generates the response parameter Bw in the windowed frequency domain.

An update W block 1500 responds to y (D), X′ and B (D), and generates a new updated Wu. A window W block 1600 converts the window parameter Wu in the frequency domain into the time domain, selects a fixed number of continuous samples in the time domain, sets the remains to zero, and then generates the window parameter Ww (D) in the windowed time domain.

This loop is repeated during the training period, and a window parameter Ww (D) to minimize errors (=Bw·X′−Ww·Y) is obtained. This window parameter Ww (D) is set for each tap of the TEQ 1010.

FIG. 16 shows a detailed configuration of each block 1300-1600. In the update B block 1300, receive signal y (D) is convoluted (filtered) by Ww (D), and an equalized response Z (D) is generated (1301). This signal passes through the FFT 1302, and response Z in the frequency domain is generated. A divider 1303 divides the equalized response Z by the encoded PRBSX′, and generates the update channel target Bu.

Then in the window B block 1400, the target Bu passes through the IFFT 1401, and the target bu (D) in the time domain is generated. A local maximum energy block 1402 calculates the total energy of each group of L taps which continue from the target bu (D), and determines the L tap group which has the maximum energy. Here, L is a window size which has a predetermined fixed value (see the window in FIG. 14). The window block 1403 sets all the remaining taps (outside the window in FIG. 17) to zero. The normalization block 1404 normalizes the window function and outputs bw (D). This signal passes through the FFT 1405, and generates the window Bw in the frequency domain.

Then the update W block 1500 updates an equalizer W by the LMS (least square method) in the frequency domain. In other words, the update W block 1500 passes the receive signal y (D) through the FFT 1502, generates Y in the frequency domain, passes the window Ww (D) in the time domain through the FFT 1505, and generates Ww in the frequency domain. The multiplier 1503 multiplies Y by Ww and generates Y·Ww. At the same time, the multiplier 1501 multiplies PRBSX′ by the window Bw and generates Bw·X′. Y·Ww is then subtracted from Bw·X′ using the subtractor 1504, and error signal E is generated. The LMS routine 1506, to which E, W and X′ are assigned, calculates the updated equalizer Wu using the following formula.

Wu=Ww−αEX″

Where α is a step size and X″ is a complex conjugate of X′.

Then, in the window W block 1600 which performs the windowing of the updated equalizer Wu, the updated equalizer Wu passes through IFFT 1600 and generates the equalizer Wu (D) in the time domain. The local maximum energy block 1601 calculates the total energy of each group of M taps which continue from the equalizer Wu (D), and determines the M tap group which has the maximum energy. Here, M is a window size which has a predetermined fixed value. The shift tap block 1602 shifts the continuing M taps in the window to the beginning of the buffer. The window block 1603 sets all the remaining taps (outside the window) to zero.

As a result, the windowed parameters of the TEQ 1010 are acquired. For details on this parameter optimization method of the equalizer, see U.S. Pat. No. 5,285,474 for example.

With this conventional coefficient optimization method for the TEQ of a DMT system, the coefficient of the TEQ is optimized only during the training period. However, the characteristics of such a line as a metal cable change depending on the environmental conditions, including temperature. Therefore, the optimization coefficient during data communication is different from the coefficient obtained during training, and the equalization characteristics in the time domain during data communication drop.

Secondly, the coefficient can be accurately optimized to be the inverse characteristics of the line during training, since the training pattern, free from inter-symbol interference, can be used. However, to correct the coefficient of the equalizer during data communication, as in the case of a single carrier system, the above mentioned prior art determines the coefficient from the input Y which contains a large quantity of inter-symbol interference (ISI) during data communication, since training is based on the input Y of the TEQ, which means that it is difficult to optimize the coefficient of the TEQ during data communication.

Thirdly, the conventional LMS algorithm used for optimizing the coefficient of the TEQ requires many FFTs which have a large processing volume, so implementing coefficient optimization by a simple processor is difficult.

### SUMMARY OF THE INVENTION

It is an object of the present invention to provide a DMT system for correcting the coefficient of the TEQ according to the characteristics of a line, even during data communication, a coefficient correction method for the TEQ of the DMT system, a receiver of the DMT system, and a DMT modem.

It is another object of the present invention to provide a DMT system for accurately correcting the coefficient of the TEQ during data communication, a coefficient correction method for the TEQ of the DMT system, a receiver of the DMT system, and a DMT modem.

It is still another object of the present invention to provide a DMT system for decreasing the coefficient correction processing volume for the TEQ, a coefficient correction method for the TEQ of the DMT system, a receiver of the DMT system, and a DMT modem.

To achieve these objects, a coefficient update method for a time domain equalizer, a receive method, a DMT system and a DMT modem of the present invention comprise a step of calculating the response characteristics of a channel and of the time domain equalizer from the output of the time domain equalizer during a training period, and updating the coefficient of the time domain equalizer, and a step of calculating the characteristic parameters of a channel and of the time domain equalizer from the output of the time domain equalizer using a synchronous signal during the data period, and updating the coefficient of the time domain equalizer.

In this aspect of the present invention, the coefficient of the TEQ can be updated by the output of the time domain equalizer (TEQ), therefore, the transient of a sync symbol to which a cyclic prefix is added can be removed, so that the coefficient of the TEQ can be accurately updated even if a sync symbol is used. Because of this, the coefficient of the TEQ is updated using a sync symbol even during data communication, so the coefficient of the TEQ 32 can be updated according to the change in characteristics, even for a channel such as a metal cable where the characteristics change as a function of a temperature change.

Also, the coefficient of the TEQ can be updated with a sync symbol using the same algorithm as the one used for the training period. Therefore, an update of the coefficient can be implemented without increasing the processing volume.

According to the coefficient update method, receive method, DMT system and DMT modem of the time domain equalizer of the present invention, the above mentioned coefficient update step has a step for calculating the coefficient of the time domain equalizer to minimize the errors of the response characteristic using the LMS, so that the coefficient can be optimized and updated accurately and easily using the LMS.

Another mode of the coefficient update method for a time domain equalizer, a receive method, a DMT system and a DMT modem of the present invention comprises a step of calculating the response characteristics of a channel and those of the time domain equalizer from the output of FFT at a subsequent stage of the time domain equalizer, and a step of calculating the coefficient of the time domain equalizer to minimize the errors of the response characteristic using the LMS.

According to this mode of the present invention, the output of FFT of the main path at a subsequent stage of the TEQ is used, so the processing volume of FFT in the coefficient correction processing can be decreased, the burden on the processor can be decreased, and a high-speed modem can be implemented with a simple configuration.

According to the present invention, the step of calculating the coefficient further comprises a step of calculating the convolution coefficient to minimize the errors of the response characteristic using the LMS, and a step of updating the coefficient of the time domain equalizer by the convolution coefficient, so that the coefficient can be updated accurately and easily.

### BRIEF DESCRIPTION OF THE DRAWINGS

FIG. 1 is a block diagram depicting a DMT system of an embodiment of the present invention;

FIGS. 2A and 2B are diagrams depicting the transmission signal format in FIG. 1;

FIG. 3 is a diagram depicting the data frame in FIG. 2;

FIGS. 4A, 4B, 4C and 4D are diagrams depicting the sync symbols in FIG. 2;

FIG. 5 is a diagram depicting the training signal in FIG. 2;

FIG. 6 is a block diagram depicting the coefficient update processing of TEQ in FIG. 1;

FIG. 7 is a diagram depicting the configuration of the convulsion circuit in FIG. 6;

FIG. 8 is a diagram depicting the convulsion operation in FIG. 7;

FIG. 9 is a diagram depicting the configuration of the divider in FIG. 6;

FIG. 10 is a diagram depicting the multiplier in FIG. 6;

FIG. 11 is a diagram depicting the configuration of a DMT system;

FIG. 12 is a diagram depicting a multi-carrier;

FIG. 13 is a diagram depicting the addition of a cyclic prefix;

FIG. 14 is a diagram depicting the removal of a cyclic prefix;

FIG. 15 is a diagram depicting a conventional coefficient update method for TEQ;

FIG. 16 is a diagram depicting a conventional coefficient update algorithm for TEQ; and

FIG. 17 is a diagram depicting a window function.

### DESCRIPTION OF THE PREFERRED EMBODIMENTS

The embodiments of this present invention will now be described in the sequence of the DMT system, TEQ coefficient optimization, and other embodiments.

[DMT system]

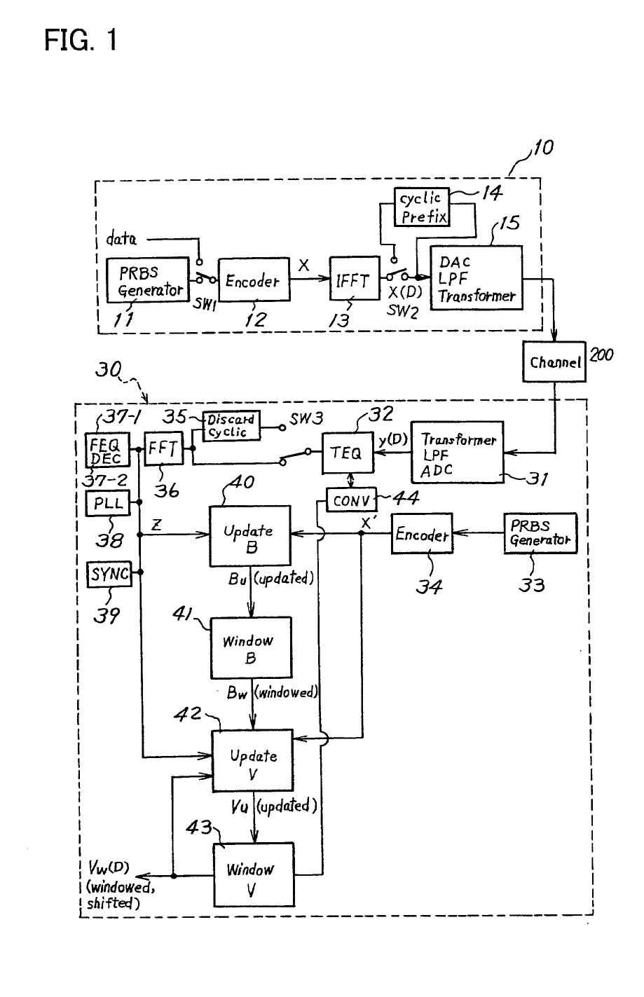

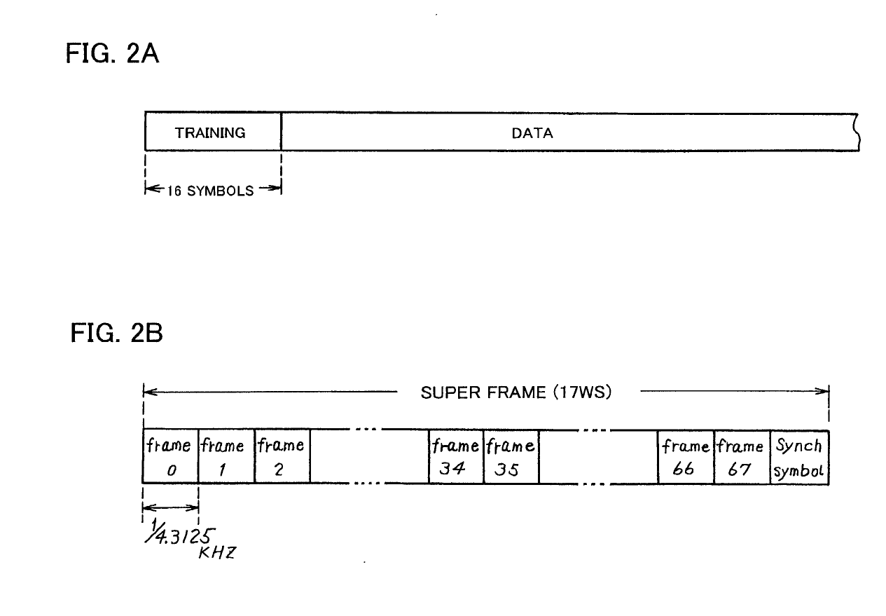

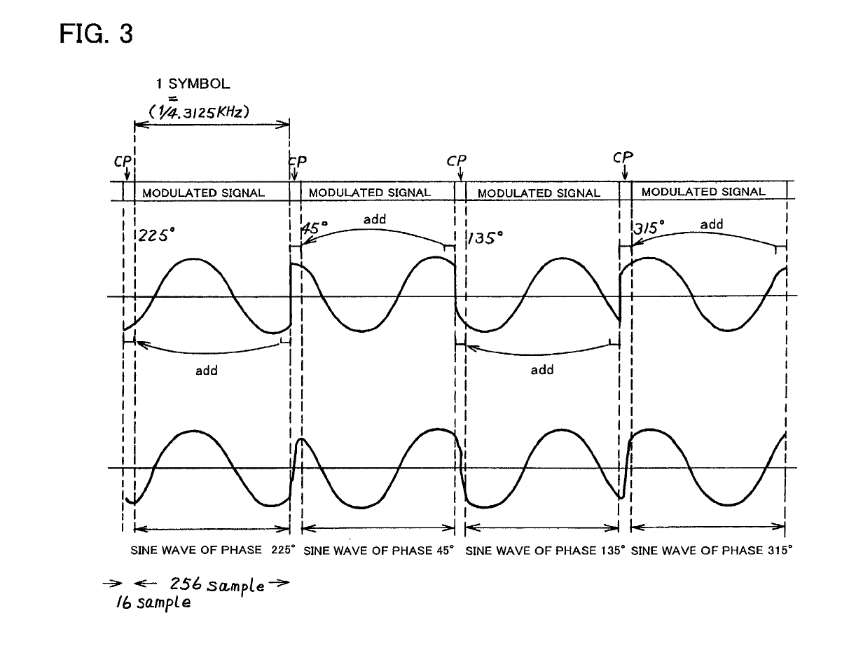

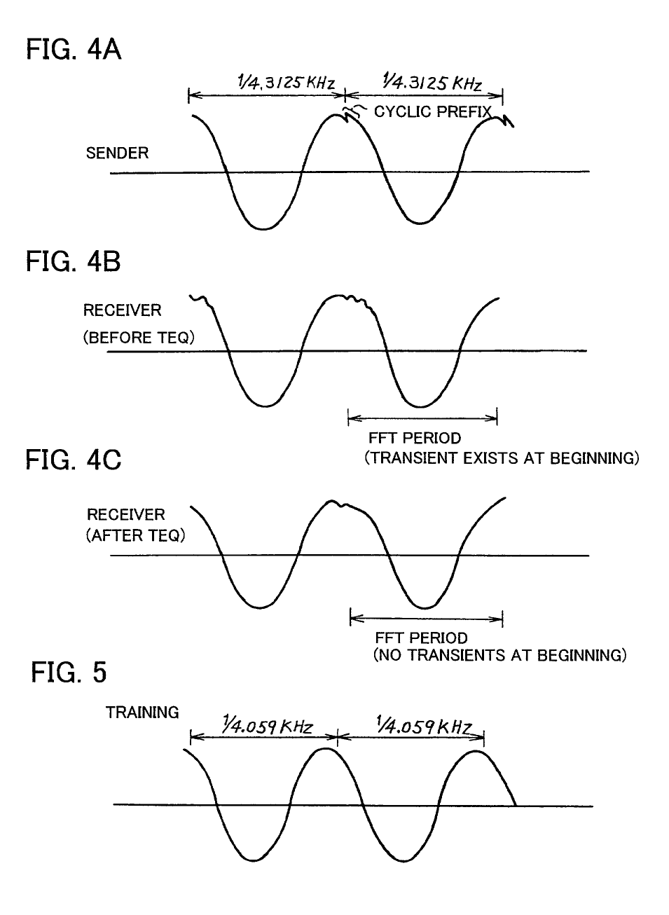

FIG. 1 is a block diagram depicting a DMT system of an embodiment of the present invention, FIG. 2A is a diagram depicting a transmission signal thereof, FIG. 2B is a diagram depicting a data signal thereof, FIG. 3 is a diagram depicting a data frame signal thereof, FIGS. 4A to 4D are diagrams depicting a sync symbol thereof, and FIG. 5 is a diagram depicting a training signal thereof.

As FIG. 1 shows, in the DMT system, a multi-carrier transmitter 10 and a multi-carrier receiver 30 are connected via a channel 200 such as a line. In the transmitter 10, an encoder 12 groups the serial input data at an Mfs bit/s rate into Mbit blocks at the symbol rate fs. A modulator 13 modulates the Mbits of each symbol by N number of separate carriers.

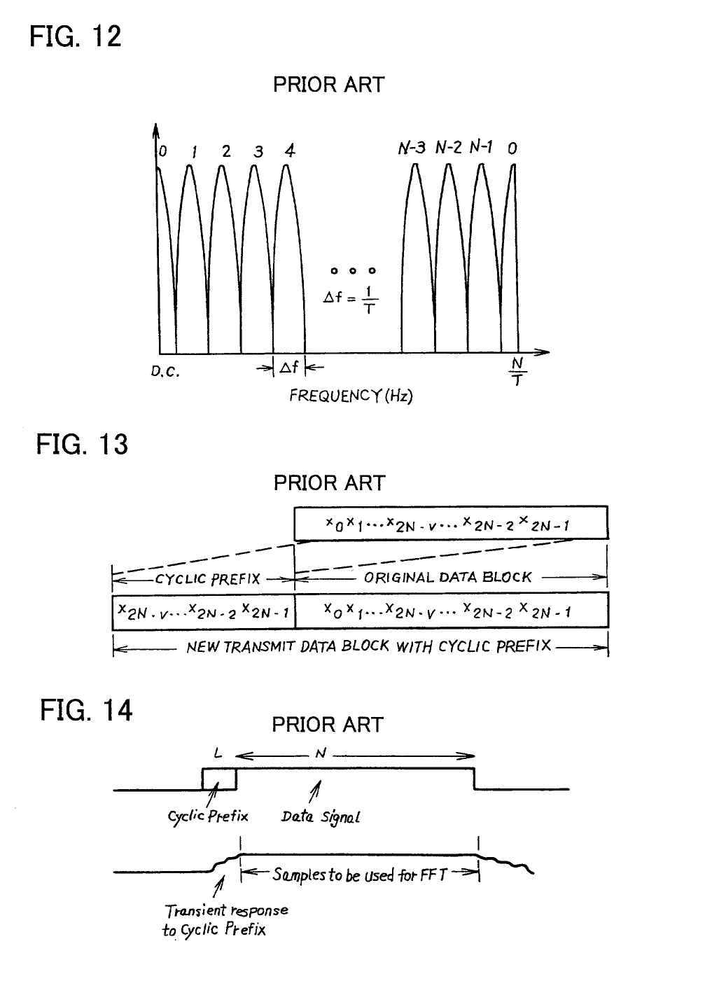

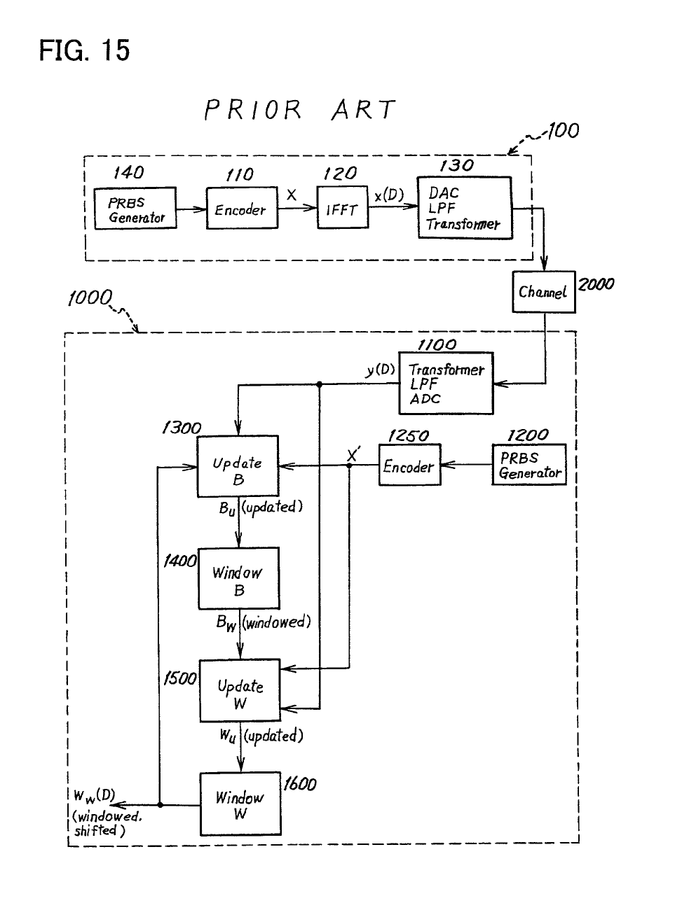

According to the present embodiment, the frequency space Δf of a sub-carrier is 4.3125 kHz in the arrangement of the multi-carriers shown in FIG. 12, and the 128^{th} sub-channel 128·Δf (552 kHz) from the 6^{th} sub-channel 6·Δf (25.875 kHz) is used. For this modulator 13, IFFT (Inverse Fast Fourier Transfer) is used, and N samples (e.g. 256 samples) of transmission signals are generated for each one of the Mbit blocks.

A cyclic prefix 14 increases the symbol length of the data signal from N to N+L so as to remove the transient of the channel 200 due to the phase discontinuity between each symbol using a receiver.

The above will be described more specifically with reference to FIG. 2 to FIG. 5. As the transmission sequence is shown in FIG. 2 A, the training signals with approximately 1000 symbols are sent at the start of the transmission, then data signals are sent. Training signals will be described later with reference to FIG. 5.

In the DMT system, 256 sampling outputs are output during 1/4000 second as an IFFF output. At each 1/4000 second, 20 samples of cyclic prefix CP are inserted into the 256 samples. Therefore the symbol timing becomes 1/4312.5 (=256/(256+20)·4000), and the sampling speed of DMT becomes 1104 k samplings/sec (=256·4.3215). This number of samples is the sample rate based on a sampling theorem to allow IDFT for the band up to the above mentioned 552 kHz.

In the DMT system, however, one symbol of the frame synchronous pattern (sync symbol) which is required for a steady data transmission must be inserted at every 68 data symbols (frame 0-frame 67). In other words, synchronization is performed in 17 ms super-frame units for communication.

To achieve this, 20 samples are shortened into 16 samples for the cyclic prefixes, as shown in FIG. 3. In other words, as shown in FIG. 3, the final 16 cyclic prefixes are placed before the sampling period of each symbol at each 256 samples of each frame. This creates a period for guarding data against ISI (inter-symbol interference).

A cyclic prefix is added after IFFT 13, and is discarded by the receiver 30. In other words, the cyclic prefix 14 is also attached before the final 16 samples of the result of IFFT 13. For clarity, only the first carrier is shown in FIG. 3.

The sync symbol shown in FIG. 2B, on the other hand, delimits the bit string derived from the generating polynomials, as shown in FIG. 4, and each bit is assigned to each carrier as one of the four phases. Since this sync symbol is a part of the data string, the cyclic prefix SP is added at the beginning. In FIG. 4A to 4D, the first carrier, which is not actually used, are shown for clarity.

The above mentioned training signal has the same pattern as the sync symbol shown in FIG. 5. The cyclic prefix SP, however, is not added. There are approximately 1000 consecutive symbols. In other words, the training pattern is the same pattern as the pattern of the sync symbol. Using this, the present invention updates the tap coefficient of the TEQ during data communication using the sync symbol.

As the following description of the receiver clearly shows, the sync symbol has the cyclic prefix SP, just like the other data frames, so, as FIG. 4B shows, the input of the TEQ is influenced by the inter-symbol interference (ISI), even if an FFT block is accurate. However, during the output of the TEQ, inter-symbol interference is minimized by the TEQ as FIG. 4C shows, so a transient is not generated in the FFT block. Therefore, the coefficient of the TEQ can be updated using sync symbols by correcting the coefficient of the TEQ during the output of the TEQ, just like training signals which have no cyclic prefix.

Returning to FIG. 1, the PRBS generator 11 generates such sync symbols and training bit string X. The switch SW1 switches the data and this bit string X. The switch SW2 outputs the digital sample of IFFT 13 to the block 130 during the training period in FIG. 2A without changing the digital sample, and outputs the digital sample of IFFT 13 to the block 130 via the cyclic prefix 14 during the data period in FIG. 2A.

This digital sample is converted by DAC/LPF/TRN 15 to an analog signal and is sent to the channel 200, DAC/LPF/TRN 15 comprising a digital-analog converter (DAC), low pass filter, and D.C separation converter.

The receiver 30 will now be described. In the receiver 30, the TRN/LPF/ADC 31, which consists of a D.C separation converter, low pass filter, and analog-digital converter, converts the analog receive signals into the digital receive signals. The pre-equalizer 32 equalizes the receive signals by the time base. Because of this, the pre-equalizer 32 is called a “time domain equalizer (TEQ)”.

The discard prefix 35 discards the added cyclic prefix L, as shown in FIG. 14, and removes the transient area between the symbols from the input of the FFT 36. The FFT (Fast Fourier Transfer) 36 demodulates the digital receive signals to the signals in the frequency domain. The FEQ (Frequency Domain Equalizer) 37-1 compensates for the intensity and the delay of each sub-channel. The decoder 37-2 decodes the data of each symbol and outputs serial data.

The PLL (Phase Locked Loop) 38 extracts the timing signals by PLL control. The synchronization circuit (SYNC) 39 detects the above mentioned sync symbol and synchronizes the transmission operation. The synchronization circuit 39 updates the FFT block by the sync symbol, and determines the operation periods of the discard prefix 35 and FFT 36. The switch SW3 outputs the output of the TEQ 32 directly to the FFT 36 during the training period, and outputs the output of the TEQ 32 to the FFT 36 via the discard prefix 35 during the data period.

In such a DMT system, the receiver 30 has a coefficient update algorithm for optimizing the equalization parameters of the TEQ 32 according to the characteristics of the channel.

As FIG. 1 shows, the PRBS generator 33 of the receiver 30 generates a copy of PRBS (bit string of sync symbols and training) at the transmission side, and the encoder 34 encodes this and generates PRBS signal X′.

The update B block 40 responds to the output Z and X′ of the FFT 36, and generates the response characteristic parameter Bu of the new and updated target channel. The window B block 41 converts the response parameter Bu in the frequency domain into the time domain, selects the fixed number of continuous samples in the time domain, sets the remains to zero, and generates the response parameter Bw in the windowed frequency domain.

Responding to Z, X′ and Bw, the update V block 42 calculates error E, and generates the shift parameter Vu of the new updated window. The window V block 43 converts the shift parameter Vu of the window in the frequency domain into the time domain, selects the fixed number of continuous samples in the time domain, sets the remains to zero, and generates the shift parameter Vw (D) of the window in the windowed time domain.

The convolution circuit 44 convolutes the tap coefficient of the TEQ 32 by the shift parameter Vw (D), and updates the tap coefficient of the TEQ 32.

In other words, according to the prior art, the response parameter of the channel is calculated from the receive signal y (D) which is the input of the TEQ, the length of the target channel is limited, then the parameter (coefficient) of the TEQ is updated using the LMS to minimize errors. The conventional algorithm to update the window parameter Ww using the LMS is given by the following formula.

Z=Y×Ww

Bu=Z/X′

E=Z−Bw×X′

Wu=Ww−α×E×Y′

where Y′ is a complex conjugate of Y.

According to the present invention, on the other hand, the combined characteristics of the channel and the TEQ 32 are regarded as the characteristics of the channel. The characteristic parameter (shift from the current parameter) of the channel is calculated from the output of the TEQ 32, the shift of the parameter (coefficient) of the TEQ to minimize errors is updated using the LMS, and the window parameter (coefficient) of the TEQ 32 is updated by this shift. The update algorithm of the window parameter Ww using the LMS according to the present invention is given by the following formula.

Z=Y×Ww

Bu=Z/X′

E=Z−Bw×X′

Vu=1−α×E×Z′

Ww(new)=Ww(old)*Vw

where Z′ is a complex conjugate of Z.

Since the coefficient of the TEQ 32 is updated from the output of the TEQ 32 in this way, the transient of the sync symbols where a cyclic prefix is added can be removed as explained in FIG. 4 (C), so the coefficient of the TEQ 32 can be accurately updated even if sync symbols are used. In this way, the coefficient of the TEQ 32 is updated once every 68 symbols, even during data communication, so that the coefficient of the TEQ 32 can be updated according to change in characteristics, even for such a channel as a metal cable, in which the characteristics change as a result of a temperature change.

Also, the coefficient of the TEQ 32 can be updated by sync symbols using the same algorithm as the one used for the training period. Therefore, an update can be implemented without increasing the processing volume.

Also as mentioned below, the output of the FFT 36 on the main path is used, so the processing volume of FFT in the coefficient correction processing can be decreased, the burden on the processor can be decreased, and a high-speed modem can be implemented with a simple configuration.

Here the transmitter and the receiver are separated, but the present invention can of course be applied to a DMT modem where both the transmitter and the receiver are integrated. In the above description, the channel is a line in the data transmission system, but the present invention can be applied to a magnetic recording/playback system. In this case, the transmitter corresponds to the magnetic writing system, the channel to the magnetic storage medium, and the receiver to the magnetic reading system.

[TEQ coefficient optimization]

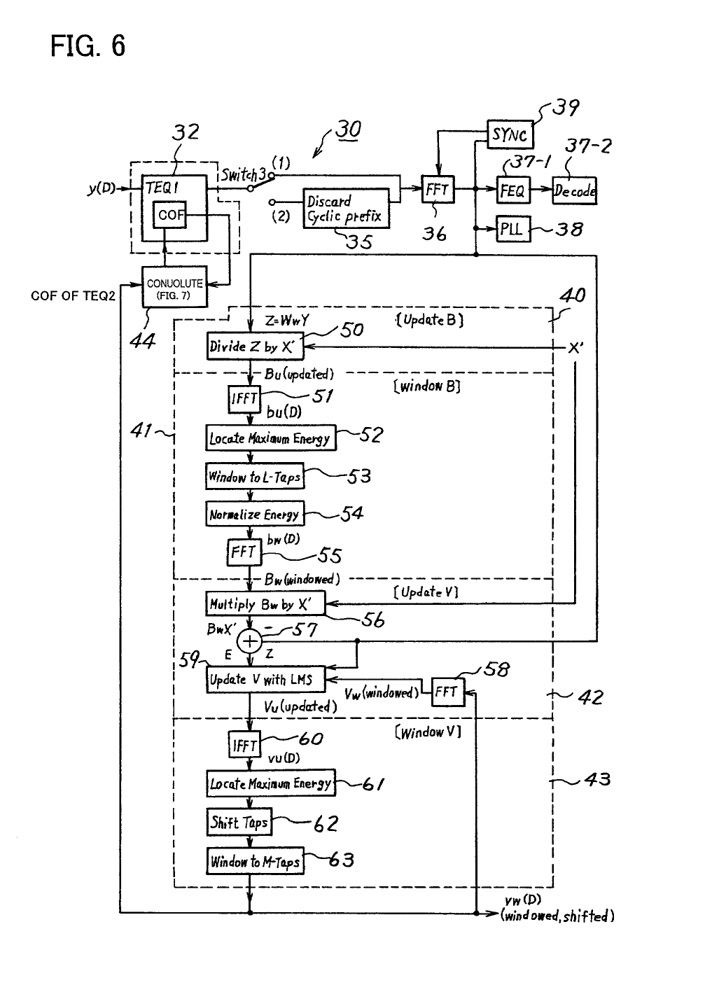

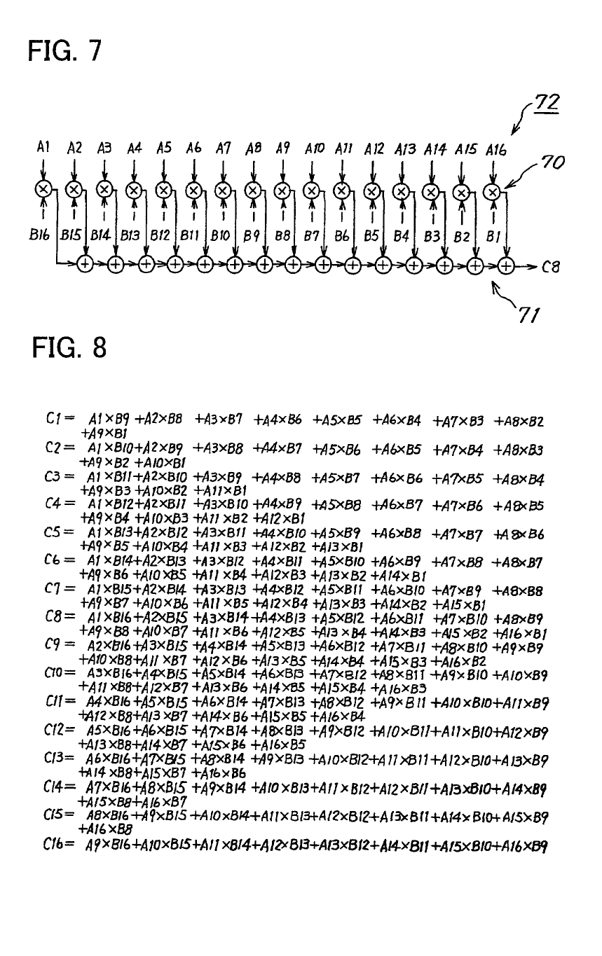

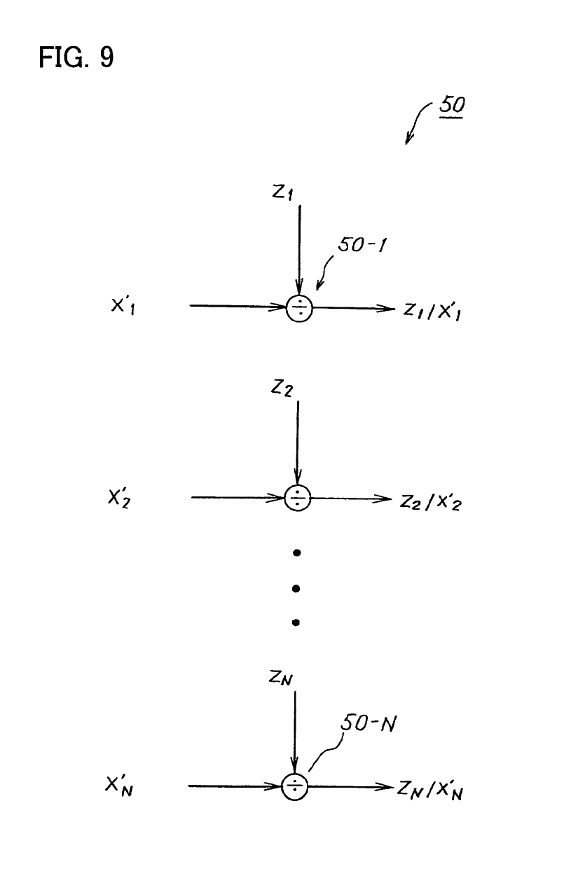

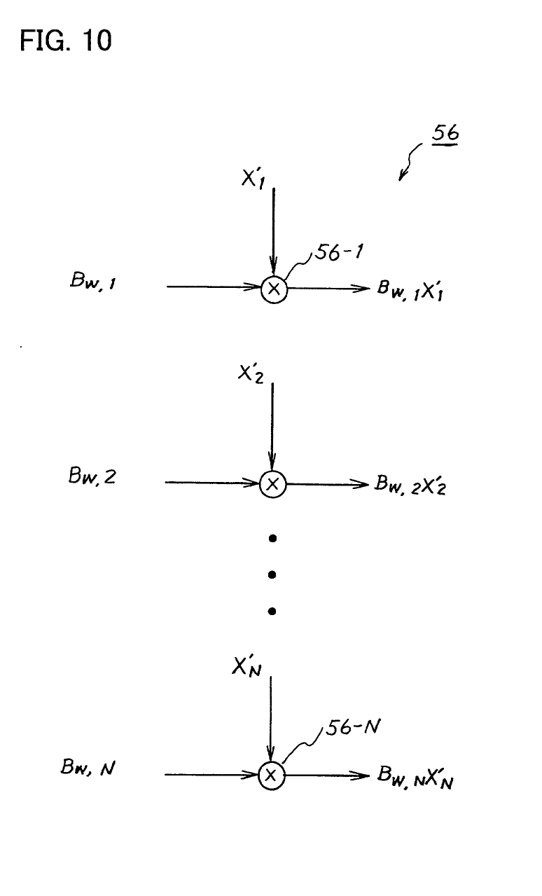

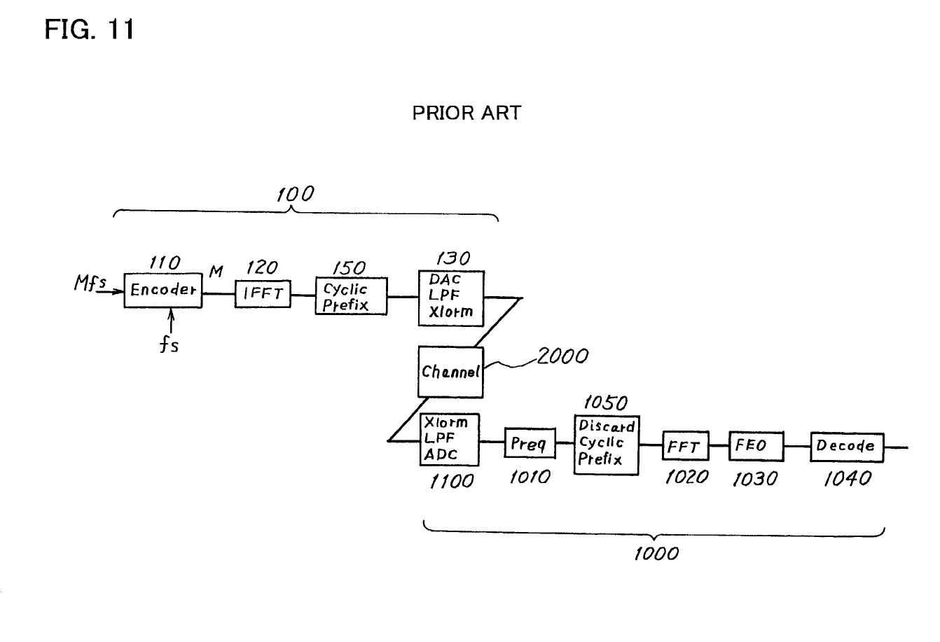

FIG. 6 is a block diagram depicting the coefficient update processing of the receiver 30 in FIG. 1, FIG. 7 is a diagram depicting a configuration of the convolution circuit thereof, FIG. 8 is a diagram depicting the convolution operation thereof, FIG. 9 is a diagram depicting the divider thereof, and FIG. 10 is a diagram depicting the multiplier thereof.

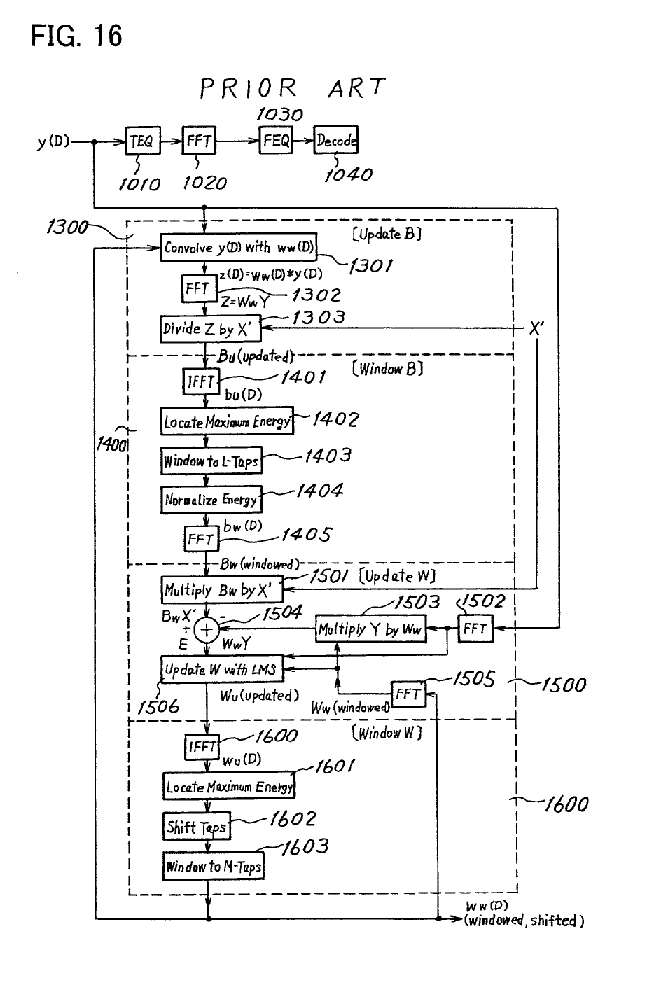

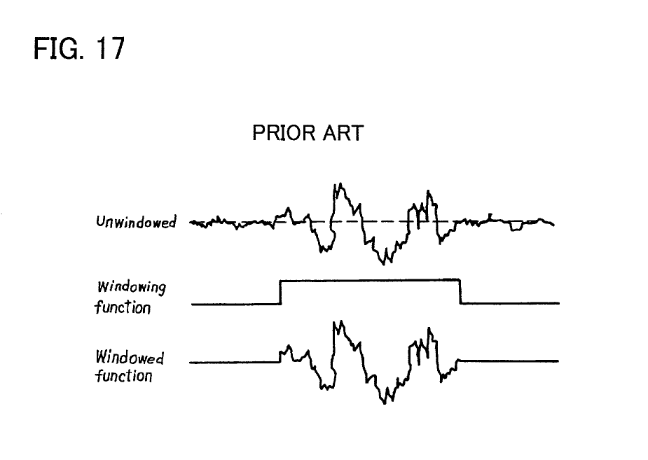

As FIG. 6 shows, in the update B block 40, the response Z (=Y·Ww) in the frequency domain, which is an output of the FFT 36, is input. The divider 50 divides the equalized response Z by the encoded PRBSX′, and generates the update channel target Bu. Since the output of the FFT 36 on the main path is used, a conventional FFT 1302 (see FIG. 16) is unnecessary.

Then in the window B block 41, the target Bu passes through the IFFT 51 and generates the target bu (D) in the time domain. The local maximum energy block 52 calculates the total energy in each group of L taps which continue from the target bu (D), and determines the L tap group which has the maximum energy. Here, L is a window size and the length of the cyclic prefix to be removed. The window block 53 sets all the remaining taps (outside the window) to zero. The normalization block 54 normalizes the window function and outputs bw (D). This signal passes through the FFT 55, and generates the window Bw in the frequency domain. The processing of this block 41 is the same as the prior art.

Then the update V block 42 updates the convolution parameter V of the convolution circuit 44 by the LMS method (least square) in the frequency domain. In other words, the update V block 42 passes the convolution parameter Vw (D) in the time domain through the FFT 58, and generates Vw in the frequency domain. The multiplier 56 multiplies PRBSX′ by the window Bw, and generates Bw·X′. The subtractor 57 subtracts Z (=Y·Ww) from Bw·X′, and generates the error signal E. The LMS routine 59 where E, Z and Vw are assigned, calculates the updated convolution parameter Vu using the following formula.

Vu=1−αEZ′

Here, α is a step size, and Z′ is a complex conjugate of Z. In this block 42, the FFT 1502 and the multiplier 1503 of the conventional block 1500 as in FIG. 16 can be omitted.

Then, in the window V block 43 which performs the windowing of the updated convolution parameter Vu in the frequency domain, the updated parameter Vu passes through the IFFT 1600, and the parameter Vu (D) in the time domain is generated. The local maximum energy block 61 calculates the total energy of each group of M taps which continued from the parameter Vu (D), and determines the M tap group which has the maximum energy. Here, M is a window size and the number of taps of the TEQ 32. The shift tap block 62 shifts the M number of continuous taps in the window to the beginning of the buffer. The window block 63 sets all the remaining taps (outside the window) to zero. This output becomes the convolution parameter Vw (D) in the time domain.

This convolution parameter Vw (D) is assigned to the convolution circuit 44. As FIG. 7 shows, the convolution circuit 44 is composed of 16 taps of the transversal equalizers (filters) 72, and has 16 multipliers 70 and 16 adders 71. The TEQ 32 is also comprised of 16 taps of transversal equalizers, and the tap coefficients A1 to A16 are input to the transversal equalizers 72 of the convolution circuit 44.

The above mentioned convolution parameter Vw (D) is input as the tap coefficients B1-B16 of the equalizer 72. Just like the known transversal equalizer, the multiplier 71 multiplies the input A by the tap coefficient B, the adder 71 adds the multiplication result, and the convolution result C is output. The convolution results C1-C16 are the calculation results shown in FIG. 8. The state in FIG. 7 is when the convolution result C8 is being calculated. Each tap coefficient A1-A16 of the TEQ 32 is updated using the convolution results C1-C16.

The divider 50 in the frequency domain in FIG. 6 is comprised of the dividers 50-1 to 50-N of each sub-channel (frequency), as shown in FIG. 9. The multipliers 56 in the frequency domain in FIG. 6 are composed of the multipliers 56-1 to 56-N of each sub-channel (frequency).

In this embodiment, the output of the FFT 36 on the main path is used, so the four conventional FFTs, normally required for a coefficient update, can be halved, to two FFTs. Since the number of FFTs where the processing volume is high can be decreased, update processing can be easily implemented using MPU and DSP. These configurations can of course be configured by hardware and/or software. And coefficient update processing is executed between the above mentioned training period and the sync symbol.

[Other embodiments]

The following variant form of the present invention is possible other than the above mentioned embodiments.

In the examples in FIG. 1 and FIG. 6, the coefficient is updated using the output of the FFT 36, but a coefficient can be updated in the training period and the sync symbol period by using the input of the FFT 36. In this case, however, the FFT must be disposed in the blocks 40 and 42.

The embodiments of the present invention have been described, but various variant forms are possible within the scope of the present invention, and these are not excluded from the scope of the present invention.

As described above, the present invention has the following effects.

The transient of the sync symbol where a cyclic prefix is added can be removed to update the coefficient of the TEQ by the output of the time domain equalizer (TEQ), so the coefficient of the TEQ can be accurately updated, even if a sync symbol is used. Since the coefficient of the TEQ is updated by a sync symbol even during data communication, the coefficient of the TEQ 32 can be updated according to the change of characteristics, even for such a channel as a metal cable, which characteristics change as a function of a temperature change.

Also, the coefficient of the TEQ can be updated by a sync symbol using the same algorithm as the one used for the training period. Therefore, an update can be implemented without increasing the processing volume.

Since the output of the FFT on the main path at a subsequent stage of the TEQ is used, the processing volume of the FFT during the coefficient correction processing can be decreased, the burden on the processor can be decreased, and a high-speed modem can be implemented with a simple configuration.

What is claimed:

1. A coefficient update method for a time domain equalizer of a DMT system which uses multi-carrier modulation, comprising;
a step of calculating the response characteristics of a channel and those of said time domain equalizer from the output of said time domain equalizer during a training period, and updating the coefficient of said time domain equalizer; and
a step of calculating the characteristic parameters of a channel and those of said time domain equalizer from the output of said time domain equalizer using a synchronization signal during a data period and updating the coefficient of said time domain equalizer.

2. The coefficient update method for the time domain equalizer according to claim 1, wherein
said coefficient update step has a step of calculating the coefficient of said time domain equalizer to minimize the errors of said response characteristic using the LMS.

3. A coefficient update method for the time domain equalizer of a DMT system which uses multi-carrier modulation, comprising;
a step of calculating the response characteristics of a channel and those of said time domain equalizer from the output of an FFT at a subsequent stage of said time domain equalizer; and
a step of calculating a coefficient of said time domain equalizer to minimize the errors of said response characteristics using the LMS.

4. The coefficient update method for the time domain equalizer according to claim 3, wherein
said step of calculating said coefficient comprises;
a step of calculating a convolution coefficient to minimize the errors of said response characteristics using the LMS; and
a step of updating the coefficient of said time domain equalizer using said convolution coefficient.

5. A receive method of a DMT system which uses multi-carrier modulation, comprising;
a time domain equalizer step of equalizing receive signals in the time domain;
a step of performing FFT processing on the output of said time domain equalizer;
a step of performing frequency domain equalizer processing on said FFT-processed output;
a step of decoding the output of said frequency domain equalizer; and
a step of calculating the response characteristic of a channel and those of said time domain equalizer from the output of said time domain equalizer according to the synchronization pattern of a training period and of a data period, and updating the coefficient of said time domain equalizer.

6. The receive method according to claim 5, wherein said coefficient update step comprises a step of calculating the coefficient of said time domain equalizer to minimize the errors of said response characteristic using the LMS.

7. A receive method of a DMT system which uses multi-carrier modulation, comprising;
a time domain equalizer step of equalizing receive signals in the time domain,
a step of performing FFT processing on the output of said time domain equalizer,
a step of performing frequency domain equalizer processing on said FFT-processed output,
a step of decoding the output of said frequency domain equalizer; and
a step of calculating the response characteristics of a channel and those of said time domain equalizer from the output of said FFT, and updating the coefficient of said time domain equalizer.

8. The receive method according to claim 7, wherein said coefficient update step further comprises a step of calculating the coefficient of said time domain equalizer to minimize the errors of said response characteristics using the LMS.

9. A DMT system which uses multi-carrier modulation, comprising;
a channel;
a transmitter which performs multi-carrier modulation on a training pattern during a training period and on a synchronization pattern during a data period, and outputs the patterns to the channel; and
a receiver which performs multi-carrier demodulation on receive signals from said channel,
wherein said receiver equalizes said receive signals in the time domain using a time domain equalizer, performs FFT processing on the output of said time domain equalizer, then equalizes said FFT-processed output in the frequency domain using a frequency domain equalizer, and also calculates the response characteristic of the channel and those of said time domain equalizer from the output of said time domain equalizer according to the training pattern and the synchronization pattern, and updates the coefficient of said time domain equalizer.

10. A DMT system which uses multi-carrier modulation, comprising;
a channel;
a transmitter which performs multi-carrier modulation on a training pattern and outputs the pattern to the channel; and
a receiver which performs multi-carrier demodulation on receive signals from said channel,
wherein said receiver equalizes said receive signals in the time domain by a time domain equalizer, performs FFT processing on the output of said time domain equalizer, then equalizes said FFT-processed output in the frequency domain using a frequency domain equalizer, and also calculates the response characteristics of said channel and those of said time domain equalizer from said FET output, and updates the coefficient of said time domain equalizer.

11. A DMT modem which uses multi-carrier modulation, comprising;
a transmitter which performs multi-carrier modulation on a training patterns during a training period and on a synchronization pattern during a data period, and outputs the patterns to a channel; and
a receiver which performs multi-carrier demodulation on receive signals from said channel,
wherein said receiver equalizes said receive signals in the time domain using a time domain equalizer, performs FFT processing on the output of said time domain equalizer, then equalizes said FFT-processed output in the frequency domain using a frequency domain equalizer, and also calculates the response characteristics of the channel and those of said time domain equalizer from the output of said time domain equalizer according to the training pattern and the synchronization pattern, and updates the coefficient of said time domain equalizer.

12. A DMT modem which uses multi-carrier modulation, comprising;
a transmitter which performs multi-carrier modulation on a training pattern and outputs the pattern to a channel; and
a receiver which performs multi-carrier demodulation on receive signals from said channel,
wherein said receiver equalizes said receive signals in the time domain using a time domain equalizer, performs FFT processing on the output of said time domain equalizer, then equalizes said FFT-processed output in the frequency domain using a frequency domain equalizer, and also calculates the response characteristics of said channel and said time domain equalizer from the output of said FFT, and updates the coefficient of said time domain equalizer.

13. A coefficient update method for TEQ wherein the coefficient algorithm of the TEQ is given by the following formula;
Z=Y×Ww
Bu=Z/X′
E=Z−Bw×X′
Vu=1−α×E×Z′
Ww(new)=Ww(old)*Vw
where Z′ is a complex conjugate of Z.

14. A coefficient update method for TEQ wherein the coefficient of the TEQ is updated by a signal after a cyclic prefix of a synchronous signal is removed.

15. A coefficient update method for TEQ wherein a training pattern and a synchronization pattern are the same pattern.
